(19) United States
(12) Patent Application Publication
(10) Pub. No.: US 2026/0286518 A1
(43) Pub. Date: Sep. 24, 2026

(54) METHOD FOR FORMING TITANIUM NITRIDE THIN FILM AND METHOD FOR FORMING ELECTRODE

(71) Applicant: JUSUNG ENGINEERING CO., LTD., Gwangju-si, Gyeonggi-do (KR)

(72) Inventors: Jeong Soo JEON, Gwangju-Si, Gyeonggi-do (KR); Yeo Na KO, Gwangju-Si, Gyeonggi-do (KR); Da Eun LEE, Gwangju-Si, Gyeonggi-do (KR); Hyo Sub JUNG, Gwangju-Si, Gyeonggi-do (KR); Jin Hyuk YOO, Gwangju-Si, Gyeonggi-do (KR); Tae Heon OH, Gwangju-Si, Gyeonggi-do (KR); Chul Joo HWANG, Gwangju-Si, Gyeonggi-do (KR)

(21) Appl. No.: 19/477,804

(22) PCT Filed: May 9, 2024
(86) PCT No.: PCT/KR2024/006255

§ 371 Date: Oct. 23, 2025

(30) Foreign Application Priority Data
May 10, 2023 (KR) 10-2023-0060723

(51) Int. Cl. C23C 16/455; C23C 16/30; H01G 4/008

(52) U.S. Cl. CPC C23C 16/4554; C23C 16/303; C23C 16/45553; C23C 16/45555; H01G 4/008

(57) ABSTRACT

A method for forming a titanium nitride thin film according to an embodiment of the present invention comprises the steps of: preparing a substrate; forming a titanium (Ti)-containing layer by spraying a precursor containing titanium (Ti) toward the substrate; and forming a titanium nitride thin film by spraying a reactant gas containing nitrogen (N) toward the substrate, wherein the precursor containing titanium (Ti) does not contain chlorine (Cl). Therefore, according to embodiments of the present invention, a titanium nitride thin film from which impurities are removed can be formed. Accordingly, the resistivity of the titanium nitride thin film can be lowered, and the electrical characteristics thereof can be improved.

### TECHNICAL FIELD

The present disclosure relates to a method for forming a titanium nitride thin film and a method for forming an electrode, and more specifically, to a method for forming a titanium nitride thin film having improved electrical characteristics and a method for forming an electrode.

### BACKGROUND ART

A capacitor includes a lower electrode formed on a substrate, a dielectric layer formed on the lower electrode, and an upper electrode formed on the dielectric layer. Herein, the upper electrode and the lower electrode are formed of a titanium nitride thin film.

In the formation of the titanium nitride thin film, the titanium nitride thin film is formed using a source precursor containing a large amount of chlorine (Cl). However, the chlorine (Cl) derived from the source precursor when forming the titanium nitride thin film causes a limitation in that the specific resistance of the electrode, that is, the specific resistance of the titanium nitride thin film, increases. In addition, when forming the titanium nitride thin film, the chlorine (Cl) contained in the source precursor penetrates an underlayer, for example, a contact layer made of a metal oxide. As a result, limitations in which the underlayer, that is, the contact layer is damaged, and thus the electrical characteristics of the capacitor deteriorate are caused.

[Prior Art Document] (Patent Document 1) Korean Patent Registration No. 10-0942958

### DISCLOSURE OF THE INVENTION

### Technical Problem

The present disclosure provides a method for forming a titanium nitride thin film having improved electrical characteristics and a method for forming an electrode.

The present disclosure also provides a method for forming a titanium nitride thin film having a low specific resistance and a method for forming an electrode.

### Technical Solution

In accordance with an exemplary embodiment, a method for forming a titanium nitride thin film includes: preparing a substrate; spraying a precursor containing titanium (Ti) toward the substrate to form a titanium (Ti) containing layer; and spraying a reactant gas containing nitrogen (N) toward the substrate to form a titanium nitride thin film, wherein the precursor containing titanium (Ti) contains no chlorine (Cl).

Generating a hydrogen (H₂) plasma to remove impurities from the titanium (Ti) containing layer may be included between the spraying of the precursor and the spraying of the reactant gas.

A process cycle may include the spraying of the precursor, the generating of the hydrogen (H₂) plasma, and the spraying of the reactant gas, and the process cycles may be carried out a plurality of times.

In accordance with the exemplary embodiment, the method for forming a titanium nitride thin film further includes generating a hydrogen (H₂) plasma to remove impurities from the titanium nitride thin film after completion of the spraying of the reactant gas.

The process cycle may further include generating a hydrogen (H₂) plasma, which is carried out after the completion of the spraying of the reactant gas, and the process cycle may be carried out a plurality of times.

The generating of the hydrogen (H₂) plasma to remove impurities between the spraying of the precursor and the spraying of the reactant gas may remove oxygen (O) contained in the titanium (Ti) containing layer, and generating a hydrogen (H₂) plasma, which is carried out after the completion of the spraying of the reactant gas, may remove oxygen (O) contained in the titanium nitride thin film.

The precursor may include tetrakis(dimethylamino)titanium (TDMAT: C₈H₂₄N₄Ti).

In accordance with an exemplary embodiment, a method for forming an electrode includes: spraying a precursor containing titanium (Ti) toward a substrate to form a titanium (Ti) containing layer; and spraying a reactant gas containing nitrogen (N) toward the titanium (Ti) containing layer to form a titanium nitride thin film, wherein the precursor containing titanium (Ti) contains no chlorine (Cl).

A primary impurity removal of generating a hydrogen (H₂) plasma to remove impurities containing oxygen (O) from the titanium (Ti) containing layer may be included between the spraying of the precursor and the spraying of the reactant gas.

A nitrogen (N) plasma may be generated using the reactant gas in the spraying of the reactant gas containing the nitrogen (N).

A process cycle may include the spraying of the precursor, the primary impurity removal, and the spraying of the reactant gas, and the process cycle may be carried out a plurality of times.

A secondary impurity removal of generating a hydrogen (H₂) plasma to remove impurities containing oxygen (O) from the titanium nitride thin film after completion of the spraying of the reactant gas may be further included, wherein the process cycle may further include the secondary impurity removal, and the process cycle including the secondary impurity removal may be carried out a plurality of times.

### Advantageous Effects

According to the embodiments of the present disclosure, it is possible to form a titanium nitride thin film in which impurities are removed. As a result, it is possible to reduce the specific resistance of the titanium nitride thin film, and it is possible to improve the electrical characteristics thereof.

### BRIEF DESCRIPTION OF THE DRAWINGS

FIG. 1 is a view illustrating a titanium nitride (TiN) thin film formed on a substrate by a method in accordance with an exemplary embodiment;

FIG. 2 is a conceptual view for describing a method of forming a titanium nitride thin film by a method in accordance with an exemplary embodiment;

FIGS. 3A-3C are process views conceptually illustrating the method of forming a titanium nitride thin film by the method in accordance with the exemplary embodiment;

FIG. 4 is a conceptual view for describing a method of forming a titanium nitride thin film by a method in accordance with another exemplary embodiment;

FIGS. 5A-5D are process views conceptually illustrating the method of forming a titanium nitride thin film by the method in accordance with the exemplary embodiment; and

FIG. 6 is a view conceptually illustrating a capacitor including an electrode formed of a titanium nitride thin film by a method in accordance with the exemplary embodiments.

### MODE FOR CARRYING OUT THE INVENTION

Hereinafter, embodiments of the present disclosure are described in more detail with reference to accompanying drawings. However, the present disclosure is not limited to the embodiments disclosed below but will be embodied in a variety of different forms. Rather, these embodiments are provided so that this disclosure will be thorough and complete, and will fully convey the scope of the present invention to persons with ordinary skill in the pertinent art. The drawings may be exaggerated to describe the embodiments of the present disclosure, and the same reference sign on the drawings denotes the same constitutional component.

The embodiments of the present disclosure relate to a method for forming a titanium nitride (TiN) thin film having improved electrical characteristics. More specifically, the embodiments of the present disclosure relate to a method for forming a titanium nitride (TiN) thin film having a low specific resistance. In addition, the embodiments of the present disclosure relate to a method for forming an electrode, in which an electrode is formed using a titanium nitride (TiN) thin film. Here, the electrode may be at least one of an upper electrode and a lower electrode in a capacitor. That is, at least one of the upper electrode and the lower electrode in the capacitor may be formed of the titanium nitride (TiN) thin film formed by the methods in accordance with the embodiments of the present disclosure.

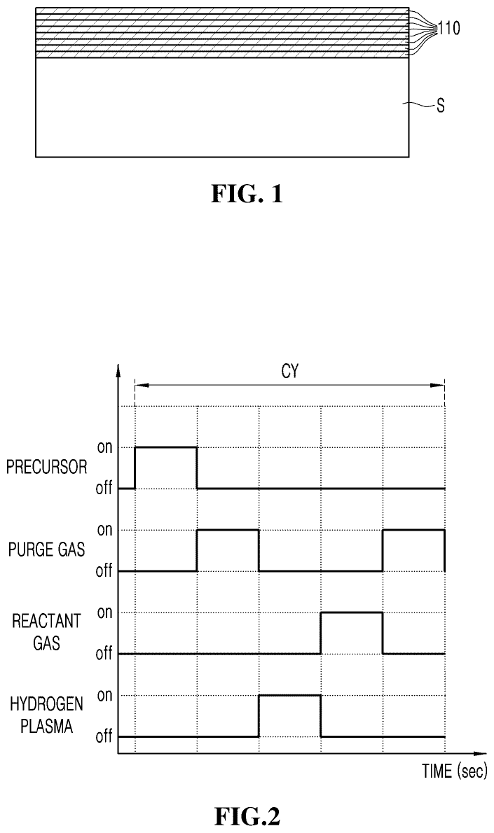

FIG. 1 is a view illustrating a titanium nitride (TiN) thin film formed on a substrate by a method in accordance with a first embodiment.

Referring to FIG. 1, a titanium nitride (TiN) thin film 110 may be formed on a substrate S. Herein, the substrate S may be a wafer, and the wafer may be any one of a Si wafer, a GaAs wafer, or a SiGe wafer. In addition, the substrate S may be made of any one of glass, metal, plastic, or a polymer film.

In addition, the substrate S may be such that one surface of the substrate S has a predetermined thin film formed thereon. For example, a contact layer of the capacitor may be formed on one surface of the substrate S, and a titanium nitride (TiN) thin film may be formed on the upper part of the contact layer by the method in accordance with the embodiment. In this case, the titanium nitride (TiN) thin film 110 formed at the upper part of the contact layer may act as the lower electrode of the capacitor.

For another example, a contact layer, a lower electrode, and a dielectric layer for the capacitor may be formed on one surface of the substrate S, and the titanium nitride (TiN) thin film 110 may be formed on the upper part of the dielectric layer by the method in accordance with the embodiment. In this case, the titanium nitride (TiN) thin film formed at the upper part of the contact layer may act as the upper electrode of the capacitor.

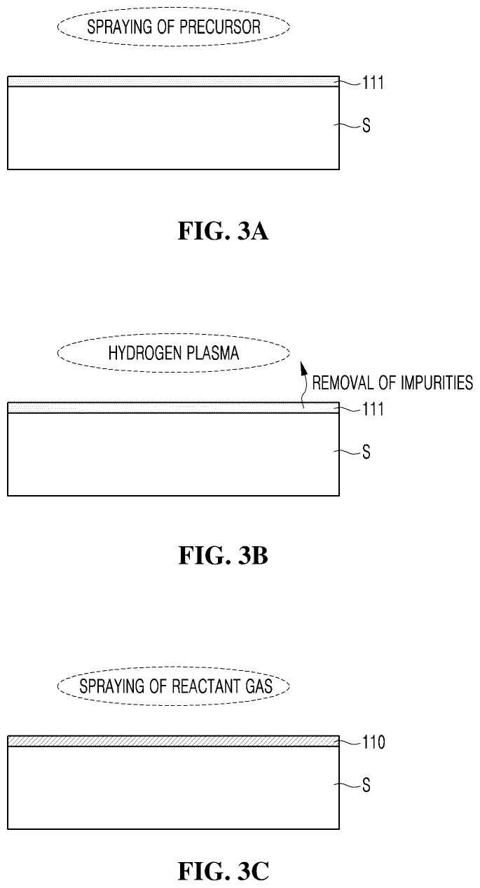

Hereinafter, with reference to FIG. 1 or FIGS. 3A-3C, a description will be made for a method of forming a titanium nitride (TiN) thin film on a substrate by a method in accordance with the first embodiment of the disclosure.

FIG. 2 is a conceptual view for describing a method of forming a titanium nitride thin film by a method in accordance with the first embodiment. FIGS. 3A-3C are process views conceptually illustrating the method of forming a titanium nitride thin film by the method in accordance with the first embodiment.

In FIG. 2, ‘on’ may mean spraying a raw material for deposition or generating plasma, and ‘off’ may mean stopping or completing spraying or generating no plasma.

Referring to FIG. 2, the method of forming the titanium nitride (TiN) thin film 110 may include a step of spraying a precursor containing titanium (Ti) (a precursor spraying step), a step of generating plasma using a gas containing hydrogen (H₂) after completion of the precursor spraying step (a hydrogen plasma generation step), and a step of spraying a reactant gas containing nitrogen (N) after completion of the hydrogen plasma generation step (a reactant gas spraying step).

In addition, the method of forming the titanium nitride thin film 110 may include at least one of a step of spraying a purge gas between the precursor spraying step and the hydrogen plasma generation step (a primary purge step) and a step of spraying a purge gas after completion of the reactant gas spraying step (a secondary purge step). Herein, an Ar gas may be used as the purge gas.

In addition, ‘the precursor spraying step—the primary purge step—the hydrogen plasma generation step—the reactant gas spraying step—the secondary purge step’ may be made into one process cycle CY for forming the titanium nitride thin film (110). In this case, at least one of the primary purge step and the secondary purge step may be omitted in the process cycle CY. Then, the process cycle CY may be repeated a plurality of times to deposit or form a plurality of the titanium nitride thin films 110, thereby laminating the same as shown in FIG. 1. In this case, the number of repetitions of the process cycle CY may be adjusted according to the target thickness to be formed.

In FIG. 1, although the respective titanium nitride thin film 110 are shown dividedly to distinguish the thin films formed by a plurality of process cycles CY, a plurality of laminated titanium nitride films 110 may have an integrated shape.

Hereinafter, each step of the process cycle CY is described in more detail.

In the step of spraying a precursor, a precursor containing titanium (Ti) is sprayed toward the substrate S. In other words, a precursor containing titanium (Ti) is sprayed into an inside of a chamber where the substrate S is charged. As a result, the precursor containing titanium (Ti) is deposited or absorbed on one surface of the substrate S to form a thin film containing titanium (Ti) (hereinafter, a titanium containing layer 111, as shown in (a) of FIG. 3.

After the completion of the step of spraying a precursor, a purge gas is sprayed into the chamber where the substrate S is charged, whereby a primary purge is carried out. In this case, for example, an argon (Ar) gas may be used as the purge gas.

On the other hand, the precursor containing titanium (Ti) may further contain, in addition to titanium (Ti), impurities such as chlorine (Cl). For example, a material used as a precursor in the related art, such as TiCl₄, contains chlorine (Cl). As a result, the titanium containing layer 111 formed on the substrate by spraying the precursor may contain chlorine (Cl). However, the chlorine (Cl) contained in the titanium containing layer 111 acts as an impurity that increases the specific resistance of the titanium nitride thin film.

Therefore, in the embodiment, a material that contains titanium (Ti) but contains no chlorine (Cl) is used as a precursor. As a more specific example, in the embodiment, a material containing tetrakis(dimethylamino)titanium (TDMAT: C₈H₂₄N₄Ti) or TDMAT is used as a precursor. The TDMAT contains titanium (Ti) but may not contain chlorine (Cl). In the embodiment, by using such a chlorine-free material (Cl) as a precursor, it is possible to prevent the chlorine (Cl) from increasing the specific resistance of the titanium nitride thin film.

In addition, a titanium (Ti) containing precursor such as TDMAT may not contain oxygen (O). By the way, oxygen in the air or in the atmosphere may bind to the precursor. As a result, the titanium containing layer 111 formed on the substrate may contain oxygen (O). In addition, the oxygen (O) contained in the titanium containing layer 111 acts as an impurity that increases the specific resistance of the titanium nitride thin film.

Therefore, in the embodiment, after spraying the precursor, a hydrogen plasma is generated using a gas containing hydrogen (H₂), whereby impurities are removed. In other words, after spraying the precursor to form the titanium containing layer 111 on the substrate S, a hydrogen plasma is generated to remove oxygen (O), that is, the impurity, from the titanium containing layer 111.

Hereinafter, the hydrogen plasma generation step is described in more detail.

The hydrogen plasma generation step is a step for removing impurities from the titanium containing layer 111, and it may be carried out after the completion of the spraying of the precursor. More specifically, in a case where the spraying of the precursor is completed, a plasma generating gas is sprayed toward an inside of a chamber or the substrate S, and power is supplied for plasma generation. In this case, a radio frequency (RF) power is applied to, for example, at least one of a chamber, a susceptor where the substrate S is attached inside a chamber, and a spray unit that sprays gas into an inside of a chamber. In addition, a gas containing hydrogen (H₂) is used as a plasma generating gas. As a more specific example, the plasma generating gas may be a hydrogen (H₂) gas. As described above, in a case where the RF power is applied and the gas containing hydrogen (H₂) is sprayed, it is possible to generate, in the inside of the chamber, a plasma including hydrogen, that is, a hydrogen plasma. As a result, the substrate S on which the titanium containing layer 111 has been formed is exposed to the hydrogen plasma, as shown in (b) of FIG. 3.

The generated hydrogen plasma reacts with the titanium containing layer 111 formed on the substrate S to remove impurities from the titanium containing layer 111. In other words, the impurities react with hydrogen (H₂) in a case where the titanium containing layer 111 is exposed to the hydrogen plasma, where the titanium containing layer 111 contains impurities such as oxygen (O). In this case, the oxygen (O) contained in the titanium containing layer 111 reacts with hydrogen (H₂) and becomes a gas, whereby the oxygen (O) leaves from the titanium containing layer 111. More specifically, the oxygen (O) contained in the titanium containing layer 111 reacts with the hydrogen plasma, whereby the oxygen (O) becomes an H₂O gas and then leaves from the titanium containing layer 111. As a result, the content of oxygen (O) contained in the titanium containing layer 111 is reduced, which makes it possible to reduce the specific resistance of each of the titanium containing layer 111 and the titanium nitride thin film that is formed after the spraying of the reactant gas.

The step of spraying a reactant gas is carried out after the completion of the hydrogen plasma generation step, and the reactant gas is sprayed toward the substrate S. In other words, the reactant gas is sprayed into the inside of the chamber where the substrate S is charged. Here, a gas containing nitrogen (N) is used as the reactant gas, and more specifically, a gas containing ammonia (NH₃) or an ammonia (NH₃) gas may be used. In a case where a reactant gas containing nitrogen (N) is sprayed, the titanium containing layer 111 is exposed to the reactant gas. As a result, the nitrogen (N) contained in the reactant gas reacts with the titanium containing layer 111 to form a titanium nitride thin film 110, as shown in (c) of FIG. 3.

At the step of spraying a reactant gas, the reactant gas may be used to generate plasma. In other words, it is possible to use the reactant gas to generate a plasma containing nitrogen (N) (that is, a nitrogen plasma).

After completion of the step of spraying a reactant gas, a purge gas is sprayed into the chamber where the substrate S is charged, whereby a secondary purge is carried out. In this case, the same gas as in the primary purge step may be used as the purge gas, and for example, argon (Ar) may be used.

The process cycle CY, which includes the precursor spraying step, the primary purge step, the hydrogen plasma generation step, the reactant gas spraying step, and the secondary purge step, which are as described above, may be carried out one time or repeatedly a plurality of times.

The titanium nitride thin film 110 formed on the substrate S in this manner has a low specific resistance. In other words, the titanium nitride thin film 110 formed by the method in accordance with the embodiment has a specific resistance as compared with a titanium nitride thin film formed by the method in the related art. This is due to the fact that a titanium (Ti) containing precursor that contains no chlorine (Cl) is used in forming the titanium containing layer 111 by spraying a precursor. As a result, it is possible to prevent the specific resistance from increasing due to chlorine (Cl), which makes it possible to form a titanium nitride thin film having a low specific resistance as compared with those in the related art. In addition, this is also due to the fact that after spraying the precursor to the substrate S to form the titanium containing layer 111, a hydrogen plasma is generated to remove oxygen (O) from the titanium containing layer 111. As a result, it is possible to reduce the oxygen (O) content contained in the titanium containing layer 111 as compared with those in the related art, which makes it possible to form the titanium nitride thin film 110 having a low specific resistance as compared with those in the related art.

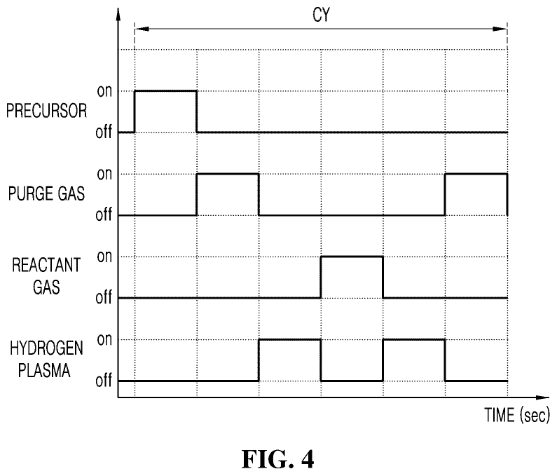

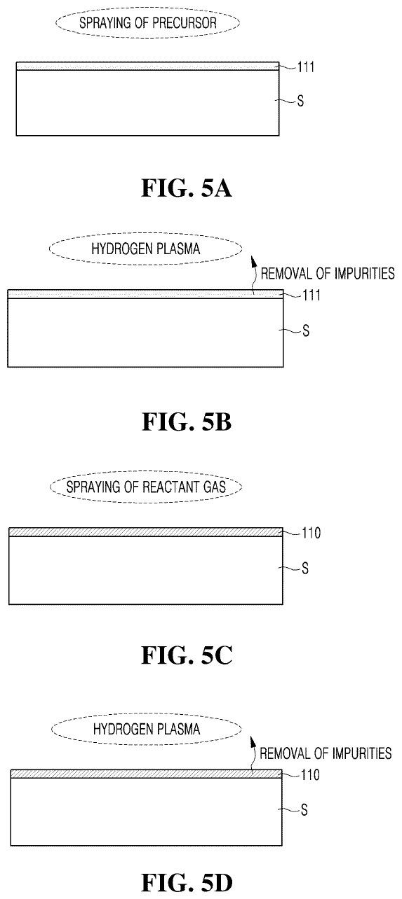

FIG. 4 is a conceptual view for describing a method of forming a titanium nitride thin film with a method in accordance with a second embodiment. FIGS. 5A-5D are process views conceptually illustrating the method of forming a titanium nitride thin film by the method in accordance with the first embodiment.

In FIG. 4, ‘on’ may mean spraying a raw material for deposition or generating plasma, and ‘off’ may mean stopping or completing spraying or generating no plasma.

In the first embodiment described in FIG. 2 and FIGS. 3A-3C, the description has been made for a case where the process cycle CY includes one hydrogen plasma generation step which is carried out between the precursor spraying step and the reactant gas spraying step. However, the step of generating a hydrogen plasma is not limited thereto, may be carried out a plurality of times, and may be carried out after carrying out the reactant gas spraying step, as shown in FIG. 4 and FIGS. 5A-5D.

Hereinafter, with reference to FIG. 4 and FIGS. 5A-5D, a description will be made for a method for forming a titanium nitride thin film in accordance with the second embodiment of the present disclosure. In this case, the explanatory description that duplicates with the first embodiment is omitted or briefly described.

Referring to FIG. 4 and FIGS. 5A-5D, the method of forming the titanium nitride thin film 110 in accordance with the second embodiment may include a step of spraying a precursor containing titanium (Ti) (a precursor spraying step), a step of generating plasma using a gas containing hydrogen (H₂) after completion of the precursor spraying step (a primary hydrogen plasma generation step), a step of spraying a reactant gas containing nitrogen (N) after completion of the primary hydrogen plasma generation step (a reactant gas spraying step), and a step of generating plasma using a gas containing hydrogen (H₂) after completion of the reactant gas spraying step (a secondary hydrogen plasma generation step).

In addition, the method of forming the titanium nitride thin film 110 may include a step of spraying a purge gas between the precursor spraying step and the primary hydrogen plasma generation step (a primary purge step) and a step of spraying a purge gas after completion of the secondary hydrogen plasma generation step (a secondary purge step). In this case, an Ar gas may be used as the purge gas.

In summary, the method of forming the titanium nitride thin film (110) in accordance with the second embodiment may include the precursor spraying step, the primary purge step, the primary hydrogen plasma generation step, the reactant gas spraying step, and the secondary purge step. In addition, ‘the precursor spraying step—the primary purge step—the primary hydrogen plasma generation step—the reactant gas spraying step—the secondary hydrogen plasma generation step—the secondary purge step’ may be made into one process cycle CY for forming the titanium nitride thin film 110. In this case, at least one of the primary purge step and the secondary purge step may be omitted in the process cycle CY.

In the method in accordance with the second embodiment, the precursor spraying steps, the primary purge step, the primary hydrogen plasma generation step, the reactant gas spraying step, and the secondary purge step are carried out in the same manner as in the first embodiment. Therefore, the explanatory description of these steps is omitted.

The secondary hydrogen plasma generation step is a step for removing impurities from the titanium nitride thin film 110, and it may be carried out after the completion of the spraying of the reactant gas. In other words, the secondary hydrogen plasma generation step removes oxygen (O), that is, impurities, which has not been removed from the primary hydrogen plasma generation step. More specifically, in the primary hydrogen plasma generation step, the oxygen (O) impurities are removed from the titanium containing layer 111. Meanwhile, in the primary hydrogen plasma generation step, impurities such as oxygen (O) contained in the titanium containing layer 111 may not be removed completely, and a part thereof may remain. As a result, the titanium nitride thin film 110 may contain impurities such as oxygen (O) when the reactant gas has been sprayed to form the titanium nitride thin film 110. Therefore, in the second embodiment, a hydrogen plasma is generated (the secondary hydrogen plasma generation step is carried out) to remove impurities from the titanium nitride thin film 110 when the reactant gas is sprayed to form the titanium nitride thin film 110.

A secondary hydrogen plasma may be generated in the same manner as in the primary hydrogen plasma generation step described above. In other words, a radio frequency (RF) power is applied to at least one of a chamber, a susceptor where the substrate S is attached inside a chamber, and a spray unit that sprays gas into an inside of a chamber Then, a gas containing hydrogen, that is, hydrogen (H₂), is sprayed into the inside of the chamber. As a result, the hydrogen plasma can be generated in the inside of the chamber. As a result, the substrate S on which the titanium nitride thin film 110 has been formed is exposed to the hydrogen plasma, as shown in FIG. 5D.

The generated hydrogen plasma reacts with the titanium nitride thin film 110 to remove impurities from the titanium nitride thin film 110. That is, impurities react with hydrogen (H₂) in a case where the titanium nitride thin film 110 is exposed to the hydrogen plasma. In this case, the oxygen (O) contained in the titanium nitride thin film 110 reacts with hydrogen (H₂) and becomes a gas, whereby the oxygen (O) leaves from the titanium nitride thin film 110. As a result, the content of oxygen (O) contained in the titanium nitride thin film 110 is reduced, which makes it possible to reduce the specific resistance of the titanium nitride thin film (110).

After the completion of the secondary hydrogen plasma generation step, a purge gas is sprayed into the chamber where the substrate S is charged, whereby a secondary purge is carried out. In this case, the same gas as in the primary purge step may be used as the purge gas, and for example, argon (Ar) may be used.

In addition, the process cycle CY, which includes the precursor spraying step, the primary purge step, the primary hydrogen plasma generation step, the reactant gas spraying step, the secondary hydrogen plasma generation step, and the secondary purge step, which are as described above, may be carried out one time or repeatedly a plurality of times.

In the above description, the description has been made for a case where a hydrogen plasma is generated (the primary hydrogen plasma generation step is carried out) between the precursor spraying step and the reactant gas spraying step, and a hydrogen plasma is generated (the secondary hydrogen plasma generation step is carried out) after spraying the reactant gas. However, the present disclosure is not limited thereto, and only one of the primary hydrogen plasma generation step and the secondary hydrogen plasma generation step may be carried out. That is, the hydrogen plasma may be generated between the precursor spraying step and the reactant gas spraying step, and the hydrogen plasma may not be generated after the spraying of the reactant gas is completed. In addition, the hydrogen plasma may not be generated between the precursor spraying step and the reactant gas spraying step, and the hydrogen plasma may be generated after the spraying of the reactant gas is completed.

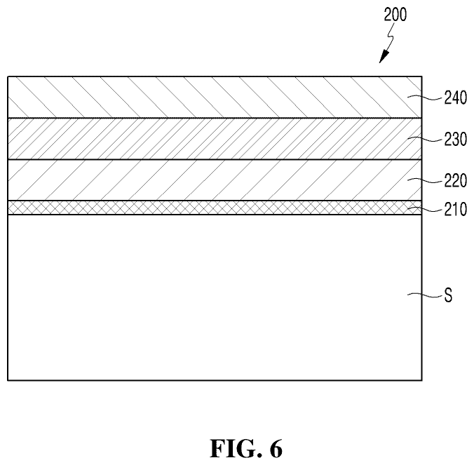

FIG. 6 is a view conceptually illustrating a capacitor including an electrode formed of a titanium nitride thin film by a method in accordance with the embodiments of the present disclosure.

Referring to FIG. 6, a capacitor 200 may include a lower electrode 220 formed on the substrate S, a dielectric layer 230 formed on the lower electrode 220, and an upper electrode 240 formed on the dielectric layer 230. In addition, the capacitor 200 may include a contact layer 210 formed on a lower side of the lower electrode 220.

The substrate S may be a semiconductor substrate. As a more specific example, the substrate S may be a wafer, and it may be any one of a Si wafer, a GaAs wafer, or a SiGe wafer.

The contact layer 210 is a layer formed between the substrate S and the lower electrode 220, where it may be formed of a metal oxide, for example, a SiO₂ thin film or an Al₂O₃ thin film.

The dielectric layer 230 is formed between the lower electrode 220 and the upper electrode 240 and may be formed of a dielectric material containing a metal oxide. As a more specific example, the dielectric layer 230 may be formed of any one of ZrO₂, Al₂O₃, TiO₂, TaO₂, and HfO₂. In addition, such a dielectric layer 230 may be formed by an atomic layer deposition (ALD) method or a chemical vapor deposition (CVD) method.

At least one among the lower electrode 220 and the upper electrode 240 may be a titanium nitride thin film formed by the methods in accordance with the embodiments of the present disclosure. For example, the titanium nitride thin film 110 may be formed by the methods in accordance with the first and second embodiments described above, thereby forming at least one of the lower electrode 220 and the upper electrode 240.

In the above description, the description has been made for a case where the titanium nitride thin film is formed by the methods in accordance with the embodiments to form at least one of the lower electrode 220 and the upper electrode 240 in the capacitor 200. However, the titanium nitride thin film 110 formed by the methods in accordance with the embodiments is not limited to the electrodes of the capacitor 200 but may be applied to various semiconductor devices or electronic devices, which are equipped with electrodes.

### INDUSTRIAL APPLICABILITY

According to the embodiments of the present disclosure, it is possible to form a titanium nitride thin film in which impurities are removed. As a result, it is possible to reduce the specific resistance of the titanium nitride thin film, and it is possible to improve the electrical characteristics thereof.

1. A method for forming a titanium nitride thin film, comprising:
preparing a substrate;
spraying a precursor containing titanium (Ti) toward the substrate to form a titanium (Ti) containing layer; and
spraying a reactant gas containing nitrogen (N) toward the substrate to form a titanium nitride thin film,
wherein the precursor containing titanium (Ti) contains no chlorine (Cl).

2. The method for forming a titanium nitride thin film according to claim 1, further comprising:
generating a hydrogen (H₂) plasma to remove impurities from the titanium (Ti) containing layer between the spraying of the precursor and the spraying of the reactant gas.

3. The method for forming a titanium nitride thin film according to claim 2,
wherein a process cycle comprises the spraying of the precursor, the generating of the hydrogen (H₂) plasma, and the spraying of the reactant gas, and
the process cycle is carried out a plurality of times.

4. The method for forming a titanium nitride thin film according to claim 3, further comprising:
generating a hydrogen (H₂) plasma to remove impurities from the titanium nitride thin film after completion of the spraying of the reactant gas.

5. The method for forming a titanium nitride thin film according to claim 4,
wherein the process cycle further comprises generating a hydrogen (H₂) plasma, which is carried out after the completion of the spraying of the reactant gas, and
the process cycle is carried out a plurality of times.

6. The method for forming a titanium nitride thin film according to claim 3,
wherein the generating of the hydrogen (H₂) plasma to remove impurities between the spraying of the precursor and the spraying of the reactant gas removes oxygen (O) contained in the titanium (Ti) containing layer, and
generating a hydrogen (H₂) plasma, which is carried out after the completion of the spraying of the reactant gas, removes oxygen (O) contained in the titanium nitride thin film.

7. The method for forming a titanium nitride thin film according to claim 1, wherein the precursor includes tetrakis(dimethylamino)titanium (TDMAT: C₈H₂₄N₄Ti).

8. A method for forming an electrode comprising:
spraying a precursor containing titanium (Ti) toward a substrate to form a titanium (Ti) containing layer; and
spraying a reactant gas containing nitrogen (N) toward the titanium (Ti) containing layer to form a titanium nitride thin film,
wherein the precursor containing titanium (Ti) contains no chlorine (Cl).

9. The method for forming an electrode according to claim 8, further comprising:
a primary impurity removal of generating a hydrogen (H₂) plasma to remove impurities containing oxygen (O) from the titanium (Ti) containing layer, between the spraying of the precursor and the spraying of the reactant gas.

10. The method for forming an electrode according to claim 8, wherein a nitrogen (N) plasma is generated using the reactant gas in the spraying of the reactant gas containing the nitrogen (N).

11. The method for forming an electrode according to claim 10, wherein a process cycle comprises the spraying of the precursor, the primary impurity removal, and the spraying of the reactant gas, and
the process cycle is carried out a plurality of times.

12. The method for forming an electrode according to claim 11, further comprising:
a secondary impurity removal of generating a hydrogen (H₂) plasma to remove impurities containing oxygen (O) from the titanium nitride thin film after completion of the spraying of the reactant gas,
wherein the process cycle further comprises the secondary impurity removal, and
the process cycle comprising the secondary impurity removal is carried out a plurality of times.

13. The method for forming a titanium nitride thin film according to claim 6, wherein the precursor includes tetrakis(dimethylamino)titanium (TDMAT: C₈H₂₄N₄Ti).
